(19) United States
(12) Patent Application Publication
(10) Pub. No.: US 2024/0025795 A1
(43) Pub. Date: Jan. 25, 2024

(54) SILICA GLASS MEMBER AND METHOD FOR PRODUCING SAME

(71) Applicant: AGC Inc., Tokyo (JP)

(72) Inventor: Kazuya SASAKI, Fukushima (JP)

(73) Assignee: AGC Inc., Tokyo (JP)

(21) Appl. No.: 18/479,852

(22) Filed: Oct. 3, 2023

Related U.S. Application Data
(63) Continuation of application No. PCT/JP2022/016901, filed on Mar. 31, 2022.

(30) Foreign Application Priority Data
Apr. 7, 2021 (JP) 2021-065433
Aug. 23, 2021 (JP) 2021-135895

(51) Int. Cl. C03C 3/06; C03B 32/00

(52) U.S. Cl. CPC C03C 3/06; C03B 32/00

(57) ABSTRACT

The present invention relates to a silica glass member having a plurality of pores, in which some or all of the plurality of pores are communication pores, and S/S0 is 1.5 or more. S: surface area obtained by a BET method for a 40 mm×8 mm×0.5 mm sample cut from the silica glass member; and S0: geometric surface area obtained based on external dimensions of the sample.

### CROSS-REFERENCE TO RELATED APPLICATIONS

This is a continuation of International Application No. PCT/JP2022/016901 filed on Mar. 31, 2022, and claims priority from Japanese Patent Application No. 2021-065433 filed on Apr. 7, 2021 and Japanese Patent Application No. 2021-135895 filed on Aug. 23, 2021, the entire contents of which are incorporated herein by reference.

### TECHNICAL FIELD

The present invention relates to a silica glass member and a method for manufacturing the same.

### BACKGROUND ART

Conventionally, in manufacture of semiconductor devices, a batch-type vertical heat treatment apparatus is used to simultaneously perform a film formation process on a plurality of wafers supported by a multistage wafer boat. Atomic layer deposition (ALD) and chemical vapor deposition (CVD) are generally used as the film formation process.

In this case, instead of product wafers, dummy wafers may be supported on an upper and lower sides of the wafer boat. By supporting the dummy wafers, it is possible to improve a flowability of gas in a processing container and a uniformity of a temperature among the product wafers, thereby improving a uniformity of film formation on the product wafers.

The dummy wafer may have, on its surface, convex and concave patterns that are formed by machining. By forming the convex and concave patterns on the dummy wafer, a difference between a surface area of the dummy wafer and a surface area of the product wafer on which convex and concave patterns are normally formed at high density is reduced, and a variation in a gas supply amount in the processing container is reduced, and thus, the uniformity of film formation among the product wafers can be further improved (see Patent Literature 1).

Patent Literature 1: JP2015-173154A

### SUMMARY OF INVENTION

Meanwhile, convex and concave patterns on a product wafer are becoming finer year by year, and along therewith, there arises a need to further increase a surface area of a dummy wafer.

In order to further increase a surface area of a dummy wafer on which convex and concave patterns are formed, it is usually necessary to narrow a pitch of convex and concave portions. However, if the convex and concave portions are formed with a narrow pitch, the convex portion has an elongated shape, which may easily cause chipping. The chipping may generate particles, which can cause a decrease in yield.

The present invention has been made in view of the above problems, and an object thereof is to provide a technique capable of obtaining a dummy wafer in which generation of particles is prevented while increasing surface area.

The present invention relates to the following [1] to [10].
[1] A silica glass member having a plurality of pores, in which
some or all of the plurality of pores are communication pores, and
S/S0 is 1.5 or more.
S: surface area obtained by a BET method for a 40 mm×8 mm×0.5 mm sample cut from the silica glass member; and
S0: geometric surface area obtained based on external dimensions of the sample.
[2] The silica glass member according to [1], in which
the S/S0 is 4 or more.
[3] The silica glass member according to [1], in which
the S/S0 is 5 or more.
[4] The silica glass member according to any one of [1] to [3], in which
the pores have an average pore size, obtained by performing image analysis on an X-ray CT image, of 30 μm to 150 μm.
[5] The silica glass member according to any one of [1] to [4], having a bulk density is 0.3 g/cm³ to 2 g/cm³.
[6] The silica glass member according to any one of [1] to [5], in which
a ratio of the number of the communication pores to the number of the plurality of pores is 30% to 100%.
[7] The silica glass member according to any one of [1] to [5], in which
a ratio of the number of the communication pores to the number of the plurality of pores is 70% to 100%.
[8] The silica glass member according to any one of [1] to [7], in which
a content of each of metal impurities including lithium (Li), aluminum (Al), chromium (Cr), manganese (Mn), nickel (Ni), copper (Cu), titanium (Ti), cobalt (Co), zinc (Zn), silver (Ag), cadmium (Cd), lead (Pb), sodium (Na), magnesium (Mg), potassium (K), calcium (Ca), cerium (Ce), and iron (Fe) is 0.5 ppm by mass or less.
[9] The silica glass member according to any one of [1] to [8] used as a dummy wafer for a vertical heat treatment apparatus in semiconductor manufacturing.
[10] A method for manufacturing a silica glass member having a plurality of pores, in which some or all of the plurality of pores are communication pores, and S/S0 is 1.5 or more where S represents a surface area obtained by a BET method for a mm×8 mm×0.5 mm sample cut from the silica glass member, and S0 represents a geometric surface area obtained based on external dimensions of the sample, the method including:
depositing silica particles generated by flame hydrolysis of a silicon compound to obtain a soot body;
densifying the soot body in an inert gas atmosphere to obtain a silica glass dense body;
making the silica glass dense body porous under a condition of at least a lower pressure or a higher temperature than that when the silica glass dense body is obtained, to obtain a silica glass porous body; and
processing the silica glass porous body to obtain the silica glass member having an arbitrary shape.

According to the present invention, it is possible to obtain a dummy wafer in which generation of particles is prevented while a surface area is increased.

### BRIEF DESCRIPTION OF DRAWINGS

FIG. 1A and FIG. 1B are diagrams illustrating a silica glass member according to an embodiment, where FIG. 1A is a perspective view of the member, and FIG. 1B is a cross-sectional view taken along the line X-X′ of FIG. 1A.

FIG. 2 is a diagram illustrating a structural change when it is assumed that only an upper surface of a silica glass member according to the embodiment is cleaned.

FIG. 3 is a flowchart showing a method for manufacturing a silica glass member according to the embodiment.

FIG. 4 is an optical microscope image in which a cut surface of a silica glass member according to Example 1 is optically polished and captured.

FIG. 5 is an optical microscope image in which a cut surface of a silica glass member according to Example 3 is optically polished and captured.

FIG. 6A is a diagram for illustrating a method for calculating an average pore size, and is a noise-removed X-ray CT image of a sample obtained by optically polishing a surface of an object to be evaluated.

FIG. 6B is a diagram for illustrating a method for calculating an average pore size, and is an image after a binarization process on FIG. 6A.

FIG. 6C is a diagram for illustrating a method for calculating an average pore size, and is an image after a watershed division process on FIG. 6B.

### DESCRIPTION OF EMBODIMENTS

Hereinafter, an embodiment according to the present invention (hereinafter, simply referred to as the present embodiment) is described in detail by using drawings. In the drawings, positional relationships such as top, bottom, left, and right are based on positional relationships shown in the drawings unless otherwise specified. Dimensional ratios in the drawings are not limited to shown ratios. In addition, in the specification, the term “to” that is used to express a numerical range includes numerical values before and after the term as a lower limit value and an upper limit value of the range, respectively. The lower limit value and the upper limit value include a rounding range.

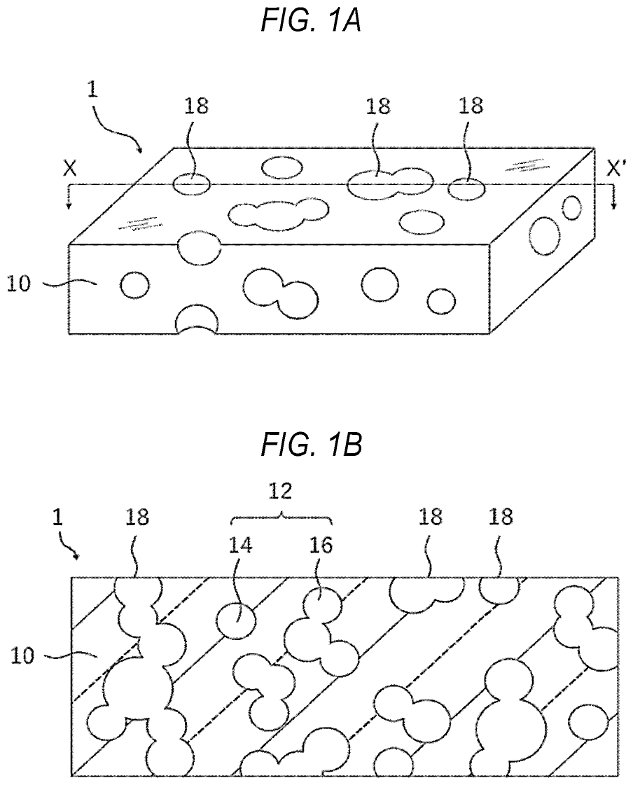

First, a structure of a silica glass member 1 according to the present embodiment will be described with reference to FIGS. 1A and 1B.

FIG. 1A is a perspective view of the silica glass member 1, and FIG. 1B is a cross-sectional view taken along the line X-X′ of FIG. 1A.

Although the silica glass member 1 illustrated in FIG. 1A is a rectangular parallelepiped, the shape thereof is not particularly limited. In the case of being used as a dummy wafer, the silica glass member 1 preferably has substantially the same shape as a product wafer.

As illustrated in FIG. 1B, the silica glass member 1 includes a silica glass portion and a plurality of pores 12. The pores 12 include non-communication pores 14 and communication pores 16.

The silica glass portion 10 mainly contains amorphous silicon oxide (SiO₂) and is transparent. The density is approximately 2.2 g/cm³. The silica glass portion 10 may contain different elements in addition to SiO₂ for an object of controlling properties of the silica glass portion 10.

The non-communication pores 14 are dispersed substantially uniformly in the silica glass member 1 and contain gas therein. The shape of the non-communication pore 14 is not particularly limited, and is substantially a spherical shape or substantially a flat spherical shape.

The communication pores 16 are formed by communicating the non-communication pores 14 adjacent to each other. FIG. 1B depicts an aspect of two-dimensional communication, but it is natural that three-dimensional communication may occur. Some or all of the pores 12 contained in the silica glass member 1 form the communication pores 16.

Some pores actually three-dimensionally communicate even though the pores do not appear to communicate in the cross-sectional view in FIG. 1B, and in the present specification, for convenience, such pores are regarded as the non-communication pores 14.

As illustrated in FIG. 1A, a plurality of pits 18 are present on a surface of the silica glass member 1. The pits 18 are formed by the non-communication pores 14 or communication pores 16 that are exposed on the surface. An appearance of the pit 18 has a substantially circular shape, a substantially elliptical shape, or a shape in which these shapes are connected. Since the silica glass member 1 having the pits 18 has an increased surface area, the silica glass member 1 is suitable as a dummy wafer.

Next, properties of the silica glass member 1 according to the present embodiment will be described.

A value (S/S0) obtained by dividing a surface area S of the silica glass member 1 by a geometric surface area S0 calculated based on external dimensions of the silica glass member 1 is 1.5 or more, preferably 3 or more, more preferably 4 or more, still more preferably 5 or more, even more preferably 6 or more, and most preferably 8 or more. In the case where S/S0 is 1.5 or more, it can be said that the surface area of the silica glass member 1 is sufficiently large, so that uniformity of film formation on a product wafer is improved. The larger the S/S0 is, the more suitable the silica glass member may be as a dummy wafer to be used together with a product wafer that has been refined in recent years. The geometric surface area S0 is an imaginary surface area obtained by assuming that the surface of the silica glass member 1 is flat with no pits 18 present.

The lower limit of the average pore size of the pores 12 is preferably 30 μm, more preferably 40 μm, and still more preferably 50 μm, and the upper limit thereof is preferably 150 μm, and more preferably 120 μm. In the case where the average pore size is within this range, an effect of increasing the surface area can be sufficiently obtained. The average pore size is an average value of pore sizes calculated on an assumption that the shape of the pores is a perfect circle. In this case, the communication pore 16 is divided into a plurality of regions by a method described later, and the pore size is obtained by regarding each divided region as one pore.

The lower limit of the bulk density of the silica glass member 1 is preferably 0.3 g/cm³, and more preferably 0.5 g/cm³, and the upper limit thereof is preferably 2 g/cm³, and more preferably 1.6 g/cm³. In the case where the bulk density is 0.3 g/cm³ or more, a sufficient strength of the silica glass member 1 can be obtained. In the case where the bulk density is 2 g/cm³ or less, the silica glass member 1 contains sufficient pores 12 and the surface area is increased, and thus, the silica glass member 1 can be suitably used as a dummy wafer.

A ratio (hereinafter, referred to as the communication pore ratio) of the number of the communication pores 16 to the number of the plurality of pores 12 (a sum of the number of the non-communication pores 14 and the number of the communication pores 16) is preferably 30% or more, more preferably 50% or more, and still more preferably 70% or more. In the case where the communication pore ratio is 30% or more, a probability that the pores forming the pits 18 are the communication pores 16 increases, and as a result, the surface area of the dummy wafer is sufficiently increased.

In the silica glass portion 10, a content of each of metal impurities including lithium (Li), sodium (Na), magnesium (Mg), aluminum (Al), potassium (K), calcium (Ca), chromium (Cr), manganese (Mn), iron (Fe), nickel (Ni), copper (Cu), titanium (Ti), cobalt (Co), zinc (Zn), silver (Ag), cadmium (Cd), and lead (Pb) is preferably 0.5 ppm by mass or less, and more preferably 0.1 ppm by mass or less. In the case where the content of each of the metal impurities is 0.5 ppm by mass or less, the silica glass member 1 can be suitably used as a member used in a semiconductor manufacturing apparatus. In the specification, ppm means parts per million and ppb means parts per billion.

Compared to a dummy wafer on which convex and concave patterns are formed, the silica glass member 1 having the structure as described above has fewer portions where chipping may occur, and thus, there is a little risk of generating particles.

The silica glass member 1 is also advantageous from a viewpoint of cleaning resistance.

Generally, the dummy wafer after use is cleaned by dry etching using a fluorine-based gas or the like or wet etching using fluoric acid or the like. In this case, depending on shapes of the convex and concave portions, the dummy wafer on which the convex and concave patterns are formed may be likely to become substantially flat due to corners of the convex and concave portions being scraped off, resulting in a decrease in the surface area.

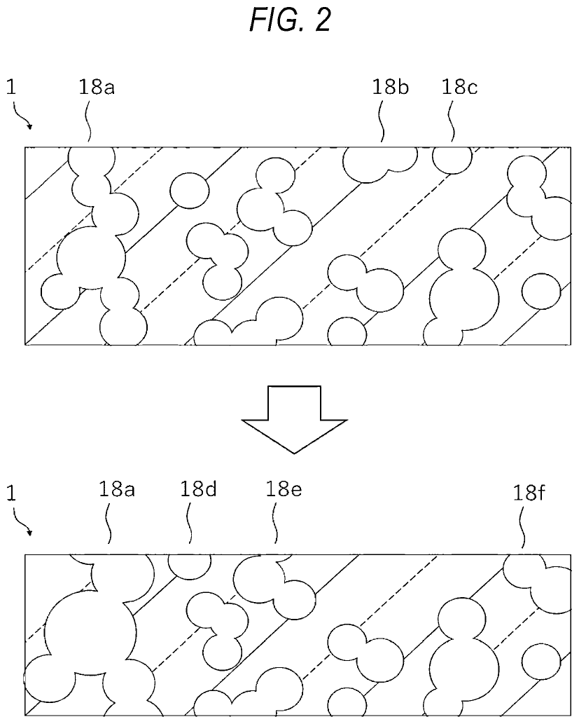

On the other hand, the silica glass member 1 is prevented from decreasing in the surface area due to cleaning. A change in the surface area of the silica glass member 1 during cleaning will be described with reference to FIG. 2. In FIG. 2, it is assumed that only an upper surface of the silica glass member 1 having three pits (18a, 18b, 18c) is cleaned. In this case, the upper surface of the silica glass member 1 and inner wall surfaces of the pits are etched by cleaning, and as a result, the pits 18b and 18c disappear, but the surface area of the inner wall of the pit 18a increases and new pits 18d, 18e, and 18f are formed. In this way, the silica glass member 1 has the pores 12 therein, thereby preventing the decrease in the surface area due to cleaning.

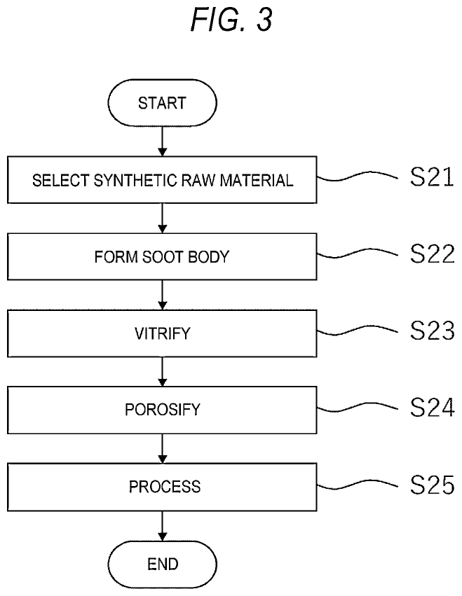

Next, a method for manufacturing the silica glass member 1 according to the present embodiment will be described with reference to FIG. 3.

In the present embodiment, a vapor-phase axial deposition (VAD) method is used as a method for synthesizing silica glass, but the method for manufacturing may be changed as appropriate as long as effects of the present invention are exhibited.

As shown in FIG. 3, the method for manufacturing the silica glass member 1 includes steps S21 to S25.

In step S21, a synthetic raw material for the silica glass is selected. The synthetic raw material for the silica glass is not particularly limited as long as the synthetic raw material is a gasifi able silicon-containing raw material, and examples thereof typically include halogen-containing silicon compounds such as silicon chlorides (for example, SiC₄4, SiHCl₃, SiH₂Cl₂, and SiCH₃Cl) and silicon fluorides (for example, SiF₄, SiHF₃, and SiH₂F₂), and halogen-free silicon compounds such as alkoxysilane represented by RₙSi(OR)₄₋ₙ, (R: an alkyl group having 1 to 4 carbon atoms, n: an integer of 0 to 3) and (CH₃)₃Si—O—Si(CH₃)₃.

Next, in step S22, the synthetic raw material is subjected to flame hydrolysis at a temperature of 1000° C. to 1500° C. to generate silica particles, and the generated silica particles are sprayed and deposited on a rotating base material to obtain a soot body. In the soot body, the silica particles are partly sintered together.

Although not shown, for an object of controlling electrical properties, after step S22, the soot body may be heat-treated in a vacuum atmosphere to dehydrate, to thereby reduce an OH group concentration. In this case, the temperature during the heat treatment is preferably 1000° C. to 1300° C., and the treatment time is preferably 1 hour to 240 hours.

Next, in step S23, the soot body is subjected to a high-temperature and high-pressure treatment in an inert gas atmosphere, whereby sintering of the silica particles in the soot body progresses and densification progresses, and as a result, a silica glass dense body is obtained. The silica glass dense body is a transparent silica glass containing almost no pores or an opaque silica glass containing minute pores. In this case, the temperature during the high-temperature and high-pressure treatment is preferably 1200° C. to 1700° C., the pressure is preferably 0.01 MPa to 200 MPa, and the treatment time is preferably 10 hours to 100 hours.

In step S23, the inert gas is dissolved in the silica glass. The inert gas is typically helium (He), neon (Ne), argon (Ar), krypton (Kr), xenon (Xe), nitrogen gas (N₂), or a mixed gas containing at least two of these, and is preferably Ar, although details will be described later. It is generally known that solubility of an inert gas in the silica glass tends to decrease as a partial pressure of the inert gas in the atmosphere decreases or as the temperature of the silica glass increases.

Next, in step S24, the silica glass dense body is subjected to a high-temperature and low-pressure treatment, whereby the inert gas dissolved in the silica glass foams, and the pores contained in the silica glass dense body thermally expands, so that porosification progresses, and as a result, the silica glass porous body having the pores 12 is obtained. In this case, the temperature during the high-temperature and low-pressure treatment is preferably 1300° C. to 1800° C., the pressure is preferably 0 Pa to 0.1 MPa, and the treatment time is preferably 1 minute to 20 hours. In the case where the treatment time is within 20 hours, there is no possibility that the pores 12 is closed due to excessive heating.

Here, a foaming mechanism will be described. As described above, solubility of the inert gas in the silica glass tends to decrease as the partial pressure of the inert gas in the atmosphere decreases or as the temperature of the silica glass increases. Therefore, in step S24, when the treatment is performed at a lower pressure or a higher temperature than that in step S23, dissolved amount of the inert gas may become supersaturated, and in this case, foaming will occur in the silica glass.

Considering the above-described mechanism, the foaming can occur even in the case where the temperature during the high-temperature and low-pressure treatment in step S24 is lower than the temperature during the high-temperature and high-pressure treatment in step S23, but the foaming is promoted and the porosification tends to progress in the case where the temperature is higher than the temperature in the high-temperature and high-pressure treatment in step S23.

Among the options for the inert gas described above, Ar is preferable from viewpoints that Ar is relatively inexpensive, its solubility in the silica glass is highly dependent on temperature, and the porosification is easily controlled.

The temperatures, the pressures, and the treatment times in the high-temperature and high-pressure treatment in step S23 and the high-temperature and low-pressure treatment in step S24 can be appropriately adjusted to change an amount of foam and a degree of pore expansion, so that the number, the pore size, the bulk density, and the like of the pores 12 contained in the silica glass member 1 can be controlled.

Finally, in step 25, the silica glass porous body is processed into an arbitrary shape by using methods such as cutting, slicing, grinding, and polishing, whereby the silica glass member 1 is obtained. In the case where the silica glass member 1 is used as a dummy wafer, the silica glass member 1 is preferably processed into substantially the same shape as the product wafer.

By the manufacturing method as described above, the silica glass member 1 suitable as a dummy wafer can be obtained without performing complicated and expensive machining for forming convex and concave patterns.

An use of the silica glass member 1 is not limited to the dummy wafer, and the silica glass member 1 can be applied to various uses within a range in which properties of the silica glass member 1 described in the present specification work effectively.

### EXAMPLES

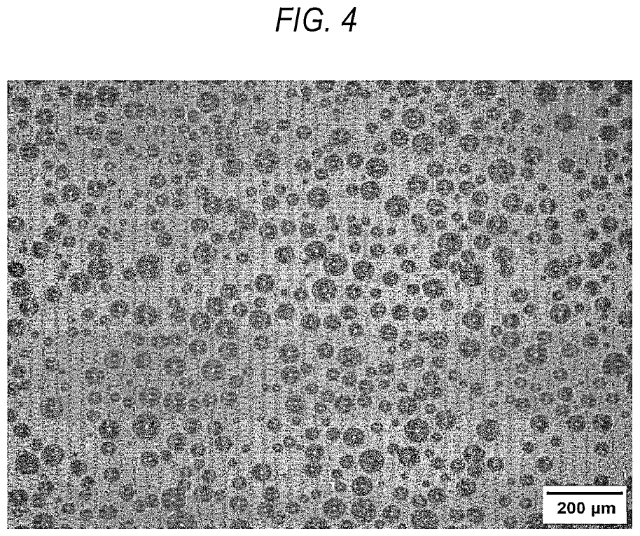

Experimental data will now be described with reference to Table 1 and FIGS. 4 to 5 and 6A to 6C.

### Examples 1 to 5

Silicon tetrachloride (SiC₄) was selected as the synthetic raw material for the silica glass, and subjected to flame hydrolysis to generate silica particles. The obtained silica particles were sprayed and deposited on a rotating base material, to obtain a soot body. Next, the soot body was placed in a heating furnace, and the heating furnace was filled with Ar gas. A high-temperature and high-pressure treatment was performed at a predetermined temperature, pressure, and treatment time to densify the soot body, followed by returning to an atmospheric pressure and allowing to cool. The silica glass dense body obtained in this case was an opaque silica glass containing minute pores. Next, a high-temperature and low-pressure treatment was performed at a predetermined temperature and treatment time, so that the silica glass dense body was made porous, followed by returning to the atmospheric pressure and allowing to cool, whereby the silica glass porous body was obtained. Finally, the silica glass porous body was taken out from the furnace, and cut, sliced, ground, and polished into a desired shape. By arbitrary combining the temperatures, the pressures, and the treatment times in the high-temperature and high-pressure treatment and the high-temperature and low-pressure treatment, the silica glass members 1 having parameters shown in Examples 1 to 5 in Table 1 were obtained.

### Examples 1 to 5 are Invention Examples

FIG. 4 shows an optical microscope image in which a cut surface of the silica glass member 1 of Example 1 was optically polished and captured. As is clear from

FIG. 4, in the silica glass member 1 of Example 1, substantially uniformly dispersed pores 12 existed, some of which existed as communication pores 16, and S/S0 was 1.9.

As a result of measuring the contents of the metal impurities in the silica glass member 1 of Example 1, Li, Mg, K, Cr, Mn, Fe, Ni, Cu, Ti, Co, Zn, Ag, Cd, Ce, and Pb were less than 3 ppb, Na was 80 ppb, Al was 30 ppb, and Ca was 10 ppb. The contents of the metal impurities were obtained by an inductively coupled plasma-mass spectrometer (ICP-MS) method after cutting the silica gas member 1 obtained as described above into an appropriate size.

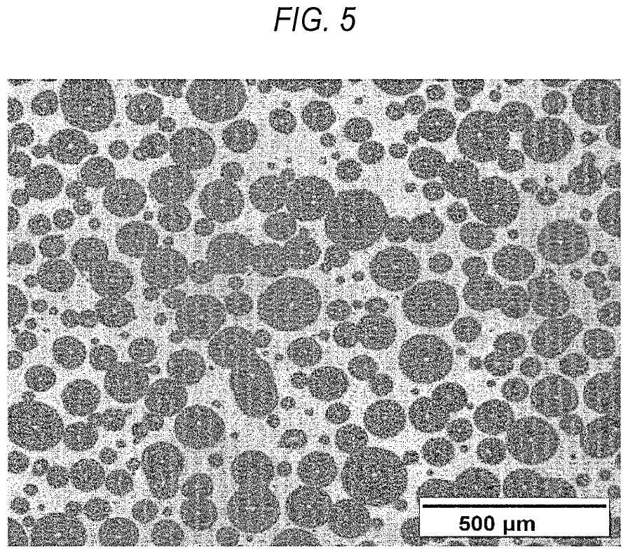

FIG. 5 shows an optical microscope image in which a cut surface of the silica glass member 1 of Example 4 was optically polished and captured. As is clear from FIG. 5, in the silica glass member 1 of Example 4, substantially uniformly dispersed pores 12 existed, some of which existed as communication pores 16, and compared to Example 1, the average pore size was larger and the communication pore ratio was higher, resulting in a high value of S/S0 of 6.9.

As described above, the silica glass members 1 of Examples 1 to 5 have a large surface area due to the inclusion of the pores 12 without machining, and the structure thereof prevents the generation of particles, so that the silica glass member 1 can be suitably used as a dummy wafer.

Parameters shown in Table 1 were obtained by methods shown below.

### (S/S0)

The surface area S was obtained by a BET method in accordance with JIS-Z8830: 2013. Specifically, five samples were prepared by cutting an object to be evaluated into plates of 40 mm×8 mm×0.5 mm, placed in a glass cell, and degassed under a reduced pressure at 200° C. for about 5 hours as a pretreatment, and then adsorption measurement of krypton (Kr) gas was performed by using a specific surface area measuring device (manufactured by Nippon Bell Co., Ltd.: BELSORP-max). The obtained value was dividing by 5 (the number of the samples) to obtain the surface area S. The surface area S was divided by the geometric surface area S0, which is based on the external dimensions of the sample, to obtain S/S0.

### (Average Pore Size)

The average pore size was obtained by the following procedures (I) to (IV).

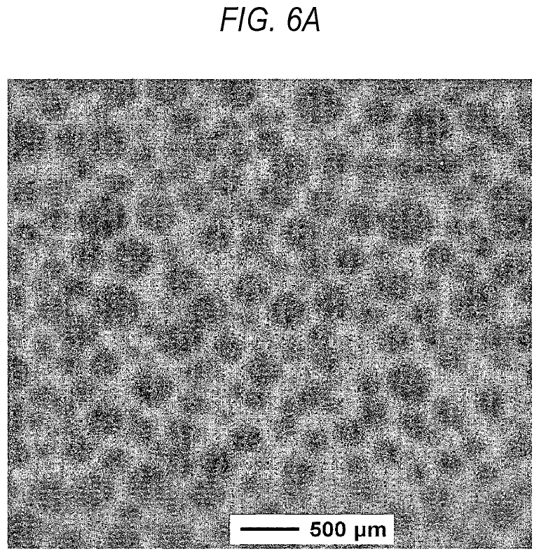

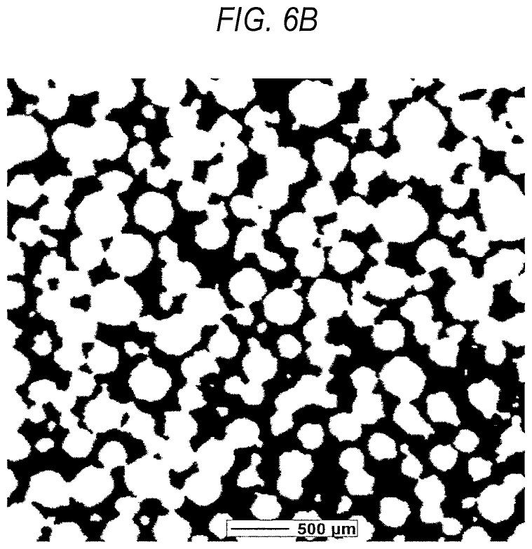

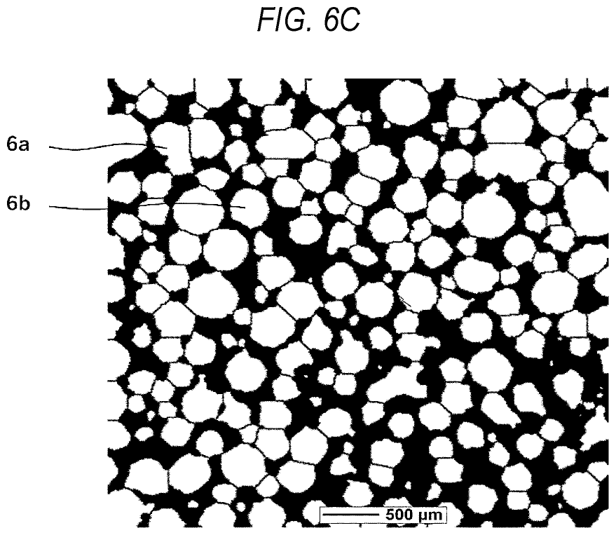

(I) First, for a sample obtained by optically polishing a surface of an object to be evaluated, an X-ray CT image was obtained by using an X-ray CT device (manufactured by Tesco: TXS-CT300), and noise was removed from the X-ray CT image by using image processing software (for example, ImageJ), so that an image as shown in FIG. 6A was obtained.

(II) Next, a binarization process was performed by using the image processing software (for example, ImageJ) to obtain an image as shown in FIG. 6B. In this case, the threshold of a luminance value of the binarization process was determined such that a ratio of an area of white regions (corresponding to the pores 12) to the area of the entire image in FIG. 6B was closest to a porosity of the object to be evaluated. Here, since the density of the silica glass substantially free of pores is 2.2 g/cm³, the porosity is obtained from the following Formula (1) by using a bulk density p which will be described later. In FIG. 6B, the white regions cut off at edges of the image were ignored in calculating the average pore size.

(Pore ratio)=(2.2−ρ)/2.2 (1)

(III) Next, an image as shown in FIG. 6C was obtained by performing a process of dividing the communication pores by a watershed division process. Here, the watershed division process is performed by the following procedures:
creating an Euclidean distance map (EDM) for the image of FIG. 6B and detecting an ultimate eroded point (UEP) which is a local maximum or vertex of the EDM;
expanding each UEP until the UEP reaches the edge of each pore, or until the UEP reaches an edge of a UEP region expanding at the communication pores; and
dividing the communication pores based on the respective expanded UEP regions.

(IV) Next, areas A of the divided region (for example, 6a) and an undivided region (for example, 6b) in FIG. 6C were respectively obtained, and a pore size D was calculated by the following Formula (2). At least 200 pore sizes D were obtained for each sample, and an average value thereof was taken as the average pore size.

D=\sqrt{4A/π} (2)

### (Bulk Density)

An object to be evaluated was cut into a rectangular parallelepiped shape of 40 mm×8 mm×0.5 mm, and the mass was measured with an electronic balance. The bulk density was obtained by dividing the mass by an apparent volume of the sample.

### (Communication Pore Ratio)

In FIG. 6C described above, the undivided white regions are regarded as non-communication pores, and the divided white regions are regarded as communication pores, and the number of the communication pores was divided by the total number of pores (the sum of the number of the non-communication pores and the number of the communication pores), so that the communication pore ratio was obtained. In FIG. 6C, the white regions cut off at the edges of the image were ignored in the calculation of the communication pore ratio.

TABLE 1

| | | Average | Bulk | Communication |
|---|---|---|---|---|
| | | pore size | density | pore ratio |
| | S/S0 | [μm] | [g/cm³] | [%] |
| Example 1 | 1.9 | 42.3 | 1.58 | 43.1 |
| Example 2 | 4.5 | 58.8 | 1.08 | 81.7 |
| Example 3 | 5.4 | 102.1 | 0.89 | 82.2 |
| Example 4 | 6.9 | 85.7 | 0.89 | 89.5 |
| Example 5 | 8.4 | 94.8 | 0.39 | 94.8 |

Although the silica glass porous body and the method for manufacturing the same according to the present invention have been described above, the present invention is not limited to the above-described embodiments and the like. Various changes, modifications, substitutions, additions, deletions, and combinations are possible within the scope of claims. These also naturally belong to the technical scope of the present invention.

The present application is based on a Japanese Patent Application (No. 2021-065433) filed on Apr. 7, 2021, and a Japanese Patent Application (No. 2021-135895) filed on Aug. 23, 2021, and the contents of which are incorporated herein by reference.

### REFERENCE SIGNS LIST

1 silica glass member
silica glass portion
12 pore
14 non-communication pore
16 communication pore
18 pit

What is claimed is:

1. A silica glass member comprising:
a plurality of pores, wherein
some or all of the plurality of pores are communication pores, and
S/S0 is 1.5 or more,
S: surface area obtained by a BET method for a 40 mm×8 mm×0.5 mm sample cut from the silica glass member; and
S0: geometric surface area obtained based on external dimensions of the sample.

2. The silica glass member according to claim 1, wherein
the S/S0 is 4 or more.

3. The silica glass member according to claim 1, wherein
the S/S0 is 5 or more.

4. The silica glass member according to claim 1, wherein
the pores have an average pore size, obtained by performing image analysis on an X-ray CT image, of 30 μm to 150 μm.

5. The silica glass member according to claim 1, having a bulk density of 0.3 g/cm³ to 2 g/cm³.

6. The silica glass member according to claim 1, wherein
a ratio of the number of the communication pores to the number of the plurality of pores is 30% to 100%.

7. The silica glass member according to claim 1, wherein
a ratio of the number of the communication pores to the number of the plurality of pores is 70% to 100%.

8. The silica glass member according to claim 1, wherein
a content of each of metal impurities including lithium (Li), aluminum (Al), chromium (Cr), manganese (Mn), nickel (Ni), copper (Cu), titanium (Ti), cobalt (Co), zinc (Zn), silver (Ag), cadmium (Cd), lead (Pb), sodium (Na), magnesium (Mg), potassium (K), calcium (Ca), cerium (Ce), and iron (Fe) is 0.5 ppm by mass or less.

9. The silica glass member according to claim 1 used as a dummy wafer for a vertical heat treatment apparatus in semiconductor manufacturing.

10. A method for manufacturing a silica glass member having a plurality of pores, in which some or all of the plurality of pores are communication pores, and S/S0 is 1.5 or more where S represents a surface area obtained by a BET method for a 40 mm×8 mm×0.5 mm sample cut from the silica glass member, and S0 represents a geometric surface area obtained based on external dimensions of the sample, the method comprising:
depositing silica particles generated by flame hydrolysis of a silicon compound to obtain a soot body;
densifying the soot body in an inert gas atmosphere to obtain a silica glass dense body;
making the silica glass dense body porous under a condition of at least a lower pressure or a higher temperature than that when the silica glass dense body is obtained, to obtain a silica glass porous body; and
processing the silica glass porous body to obtain the silica glass member having an arbitrary shape.
